(19) United States
(12) Patent Application Publication
(10) Pub. No.: US 2026/0213747 A1
(43) Pub. Date: Jul. 23, 2026

(54) SIGNAL TRANSMISSION DEVICE, ELECTRONIC DEVICE AND VEHICLE

(71) Applicant: ROHM CO., LTD., Kyoto-shi (JP)

(72) Inventor: Koki MISHIMA, Kyoto-shi (JP)

(21) Appl. No.: 19/566,112

(22) Filed: Mar. 13, 2026

Related U.S. Application Data
(63) Continuation of application No. PCT/JP2024/027319, filed on Jul. 31, 2024.

(30) Foreign Application Priority Data
Sep. 15, 2023 (JP) 2023-150127

(51) Int. Cl. H03K 17/691; H03K 19/0175

(52) U.S. Cl. CPC H03K 17/691; H03K 19/0175

(57) ABSTRACT

A signal transmission device comprises: an insulation element for performing signal transmission between a primary circuit system and a secondary circuit system while providing insulation therebetween; a self-diagnosis circuit which is provided in the secondary circuit system and performs self-diagnosis of the secondary circuit system; a storage circuit which is provided in the secondary circuit system and in which memory access is permitted after completion of the self-diagnosis; and a transmission circuit which is provided in the secondary circuit system and outputs a transmission pulse signal to the insulation element. The transmission circuit generates one pulse or a group of a plurality of pulses in the transmission pulse signal at the completion timing of each of the self-diagnosis and the memory access and continues generating pulses at the period of a first time in the transmission pulse signal when an abnormality in the memory access is being detected.

### CROSS REFERENCE TO RELATED APPLICATIONS

This application is a continuation under 35 U.S.C. § 120 of PCT/JP2024/027319, filed Jul. 31, 2024, which is incorporated herein by reference, and which claimed priority to Japanese Application No. 2023-150127, filed Sep. 15, 2023. The present application likewise claims priority under 35 U.S.C. § 119 to Japanese Application No. 2023-150127, filed Sep. 15, 2023, the entire content of which is also incorporated herein by reference.

### TECHNICAL FIELD

The present disclosure relates to a signal transmission device, an electronic device, and a vehicle.

### BACKGROUND ART

Conventionally, a signal transmission device that performs signal transmission between a primary circuit system and a secondary circuit system while keeping electrical isolation between the primary circuit system and the secondary circuit system has been used for various applications (power supply devices, motor driving devices, etc.).

Patent Document 1 attributed to the applicant of the present application may be mentioned as one example of prior arts related to the above description.

### CITATION LIST

### Patent Literature

Patent Document 1: WO 2022/070944 A1

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram illustrating a detailed configuration of a signal transmission device.

FIG. 11 is a diagram illustrating one configuration example of an electronic device on which the signal transmission device is mounted.

FIG. 12 is a diagram illustrating switching control of operation mode.

FIG. 13 is a diagram illustrating a first embodiment (comparative example) of the signal transmission device.

FIG. 14 is a diagram illustrating a second embodiment (outline) of the signal transmission device.

FIG. 15 is a diagram illustrating a second embodiment (first essential) of the signal transmission device.

FIG. 16 is a diagram illustrating a first sharing example of an insulation element.

FIG. 17 is a diagram illustrating the second embodiment (second essential) of the signal transmission device.

FIG. 18 is a diagram illustrating a second sharing example of the insulation element.

FIG. 19 is a view showing an appearance of a vehicle.

### DESCRIPTION OF EMBODIMENTS

### Signal Transmission Device (Basic Configuration)

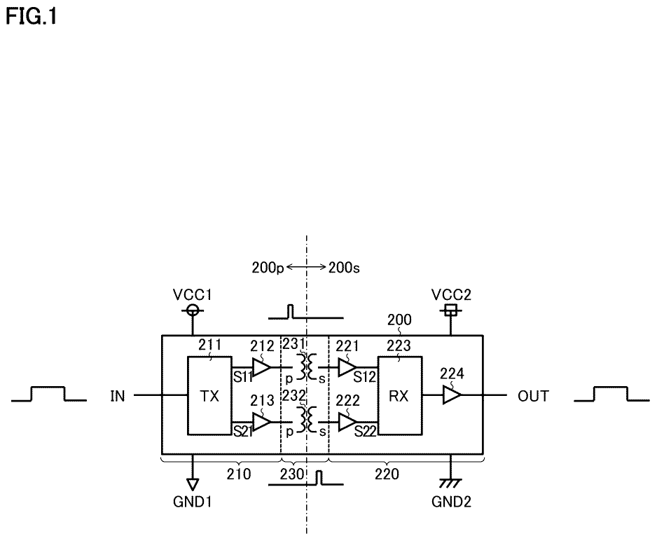

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

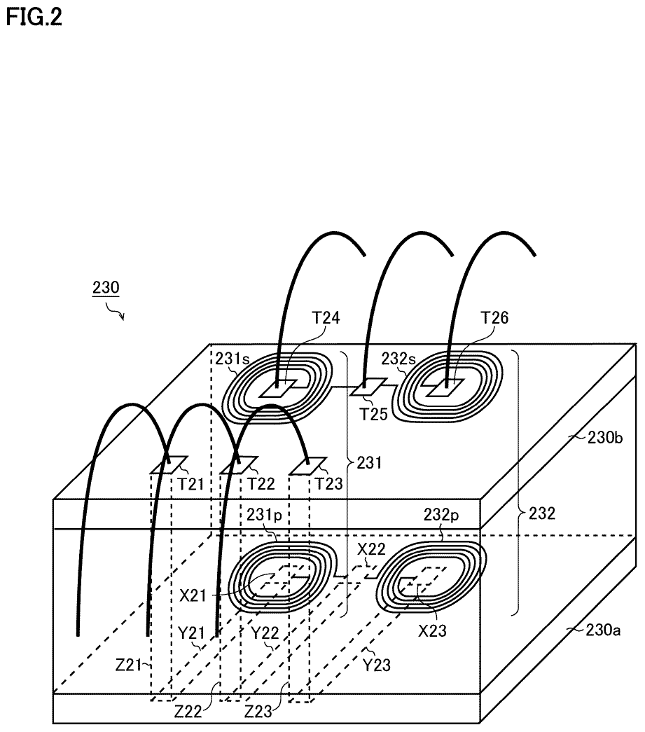

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

### Transformer Chip (Two-Channel Type)

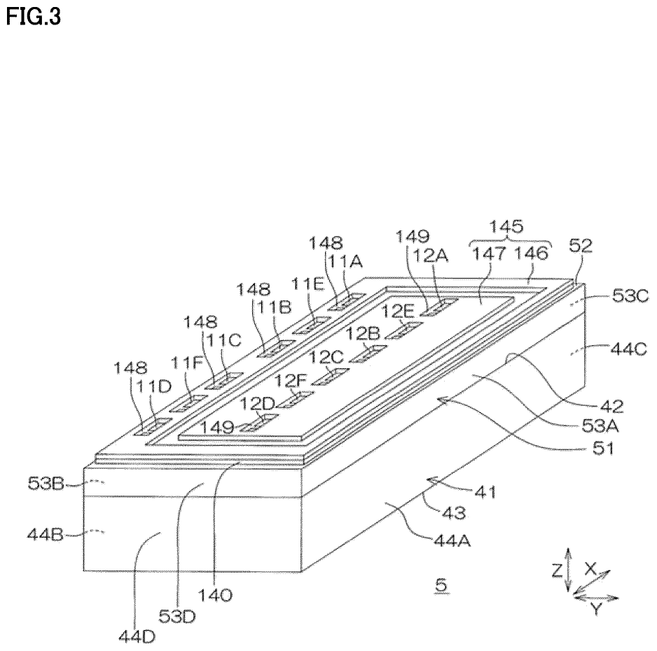

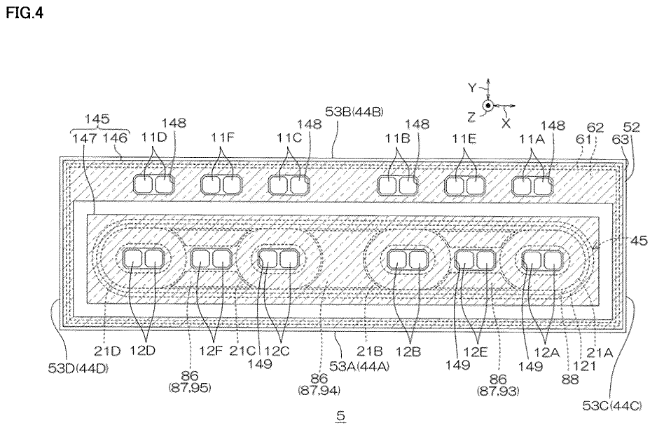

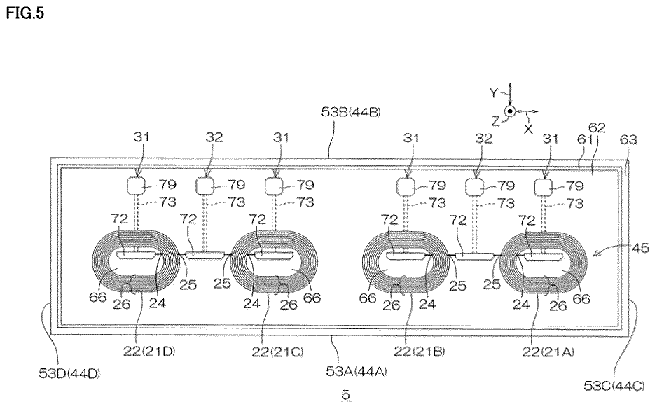

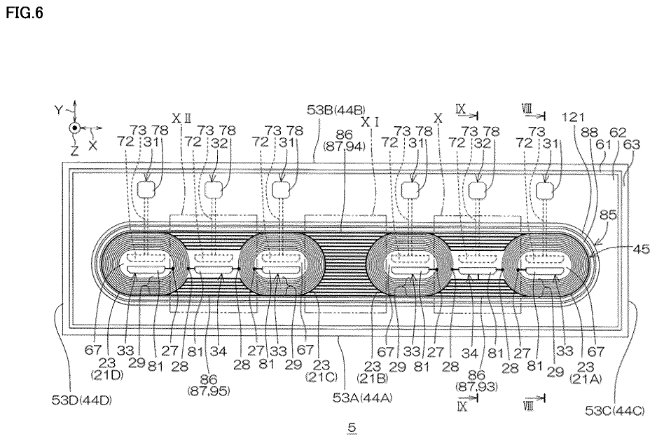

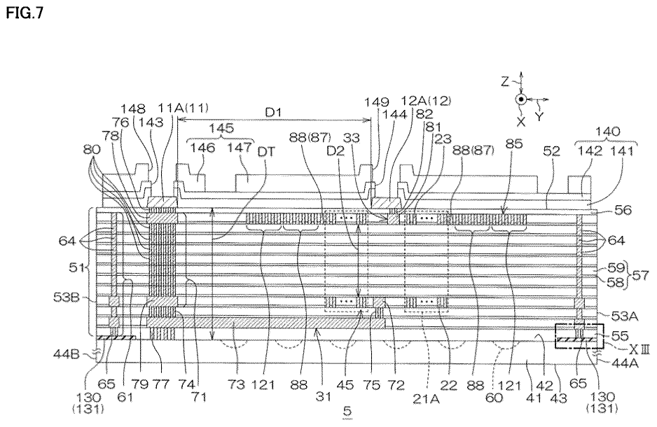

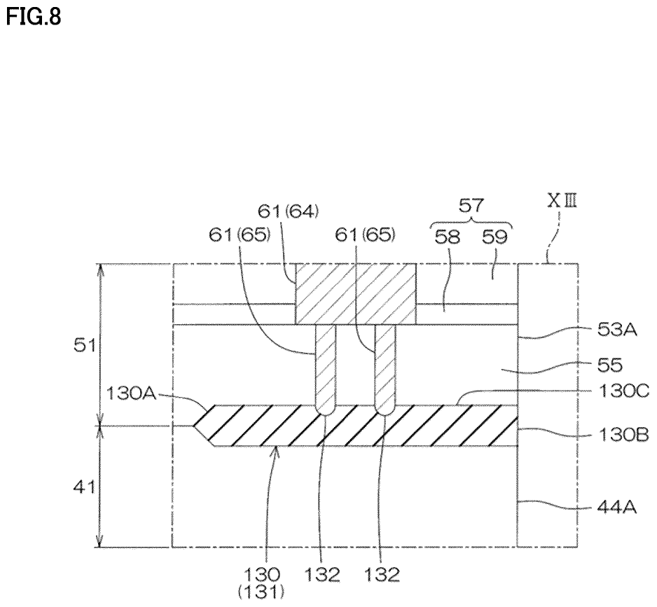

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIGS. 3 to 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIGS. 5 to 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIGS. 5 and 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73 and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIGS. 6 and 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIGS. 6 and 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIGS. 5 to 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view, and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIGS. 7 and 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low- and high-potential terminals 11 and 12, it is possible to suppress unnecessary conduction between the high-potential terminal 12 and the sealing conductor 61. Likewise, in a case where a voltage is applied to the second functional device 60 via the low- and high-potential terminals 11 and 12, it is possible to suppress unnecessary conduction between the low-potential terminal 11 and the sealing conductor 61.

The embodiment described above deals with an example where a second functional device 60 is formed. The second functional device 60, however, is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

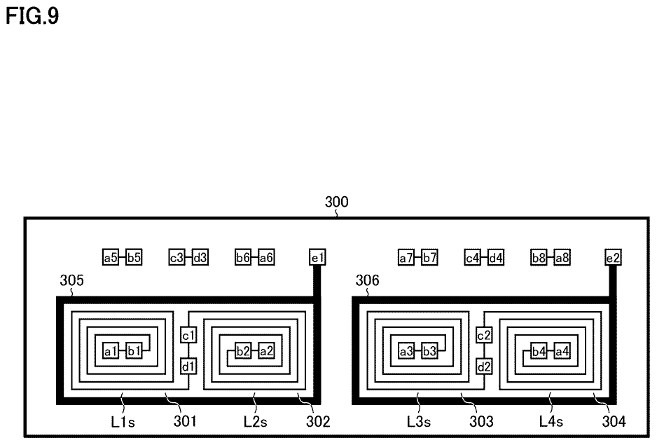

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### Signal Transmission Device (Detailed Configuration)

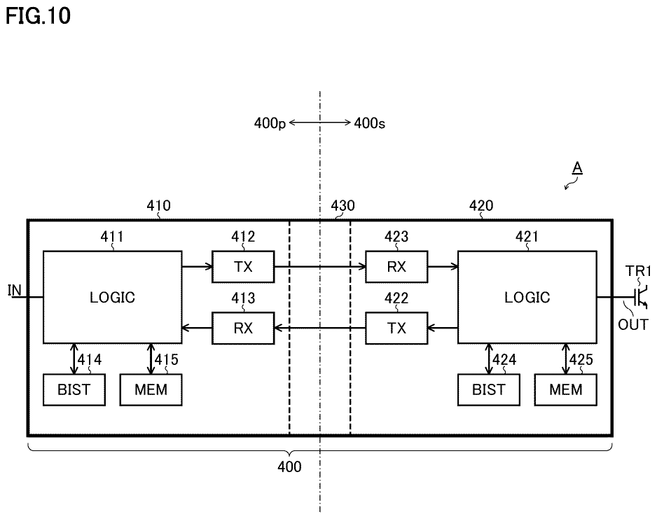

FIG. 10 is a diagram illustrating a detailed configuration of a signal transmission device. As shown in this figure, the signal transmission device 400 of this configuration example is mountable on an electronic device A together with various discrete components (drive-targetable switching device TR1 and the like). The signal transmission device 400 has a first die 410, a second die 420, and a third die 430 sealed in a single package.

Like the foregoing signal transmission device 200 (FIG. 1), the signal transmission device 400 may also be a semiconductor integrated circuit device (so-called isolated gate driver IC) which, while keeping isolation between a primary circuit system 400p and a secondary circuit system 400s, generates an output pulse signal OUT responsive to an input pulse signal IN to drive the switching device TR1.

Further, the signal transmission device 400 is widely applicable to overall applications (motor drivers dealing with high voltage, DC/DC converters, AC/DC converters, inverters, etc.) that involve performing signal transmission between the primary circuit system 400p and the secondary circuit system 400s while keeping isolation therebetween.

The first die 410 is provided in the primary circuit system 400p. The first die 410 corresponds to the foregoing controller chip 210 (=first chip). According to the figure, the first die 410 includes a logic 411, a transmission circuit 412, a reception circuit 413, a self-diagnosis circuit 414, and a storage circuit 415.

The logic 411 (=corresponding to signal processing circuit) performs bidirectional isolated communications with the second die 420 via the transmission circuit 412 and the reception circuit 413. Also, the logic 411 controls self-diagnosis of the first die 410 by the self-diagnosis circuit 414 as well as memory access (read or write) to the storage circuit 415.

The transmission circuit 412 drives an insulation element (not shown) of the third die 430 in response to an instruction from the logic 411 to transmit a pulse signal to the second die 420.

The reception circuit 413, upon receiving a pulse signal transmitted from the second die 420 via the third die 430, transmits the pulse signal to the logic 411.

The self-diagnosis circuit 414 executes a self-diagnosis (so-called BIST [built-in se test]) as to whether or not each component of the first die 410 is in a correctly workable state. A target of this self-diagnosis may be a comparator intended for detection of various types of faulty states, or the like. In this self-diagnosis, for example, it may be decided whether or not, with a dummy fault signal given to a diagnosis-targeted comparator, a faulty state is correctly detected.

The storage circuit 415 stores various types of data that are processable by the lo 411. In addition, the storage circuit 415 may include nonvolatile memory such as OTPROM [one-time programmable read only memory] or MTPROM [multiple-time PROM]. Also, the storage circuit 415 may include volatile memory such as a register.

The second die 420 is provided in the secondary circuit system 400s. The second die 420 corresponds to the foregoing driver chip 220 (=second chip). According to the figure, the second die 420 includes a logic 421, a transmission circuit 422, a reception circuit 423, a self-diagnosis circuit 424, and a storage circuit 425.

The logic 421 performs bidirectional isolated communications with the first die 410 via the transmission circuit 422 and the reception circuit 423. Also, the logic 421 controls self-diagnosis of the second die 420 by the self-diagnosis circuit 424 as well as memory access to the storage circuit 425.

The transmission circuit 422 drives an insulation element (not shown) of the third die 430 in response to an instruction from the logic 421 to transmit a pulse signal to the first die 410.

The reception circuit 423, upon receiving a pulse signal transmitted from the first die 410 via the insulation element (not shown) of the third die 430, transmits the pulse signal to the logic 421.

The self-diagnosis circuit 424 executes a self-diagnosis (so-called BIST) as to whether or not each component of the second die 420 is in a correctly workable state. A target of this self-diagnosis may be a comparator intended for detection of various types of faulty states, or the like. In this self-diagnosis, for example, it may be decided whether or not, with a dummy fault signal given to a diagnosis-targeted comparator, a faulty state is correctly detected.

The storage circuit 425 stores various types of data that are processable by the lo 421. In addition, the storage circuit 425 may include nonvolatile memory such as OTPROM or MTPROM. Also, the storage circuit 425 may include volatile memory such as a register.

The third die 430 is a semiconductor chip in which an insulation element (not shown) is integrated to achieve bidirectional signal transmission between the first die 410 and the second die 420 while keeping isolation therebetween. The insulation element may be a transformer as an example. That is, the third die 430 corresponds to the foregoing transformer chip 230 (=third chip).

During signal transmission from the first die 410 to the second die 420, there is formed a first signal transmission path ranging from the logic 411 via the transmission circuit 412 and the reception circuit 423 up to the logic 421. During signal transmission from the second die 420 to the first die 410, there is formed a second signal transmission path ranging from the logic 421 via the transmission circuit 422 and the reception circuit 413 up to the logic 411.

In addition, the signal transmission device 400 of this configuration example includes a third die 430, which has only an insulation element mounted thereon, independently in addition to the first die 410 and the second die 420. With this configuration, the first die 410 and the second die 420 can be formed each by a common low-to middle-withstand-voltage process (with a withstand voltage of several volts to several tens of volts). This eliminates the need for a dedicated high-withstand-voltage process (with a withstand voltage of several kilovolts), and helps reduce manufacturing costs.

Also, the first die 410 and the second die 420 can be made up each by field-proven existing process. This eliminates the need for newly conducting a reliability test, contributing to reductions in development period and development cost.

The switching device TR1 may be, for example, an upper switching device and a lower switching device of a half-bridge output stage or a full-bridge output stage. The half-bridge output stage or the full-bridge output stage may be used as a load drive means such as a motor driver, or as a power transform means such as an inverter. As shown in the figure, the switching device TR1 may be an IGBT. Further, the switching device TR1 may be substituted by a MOSFET [metal oxide semiconductor field effect transistor] or the like.

### Electronic Device

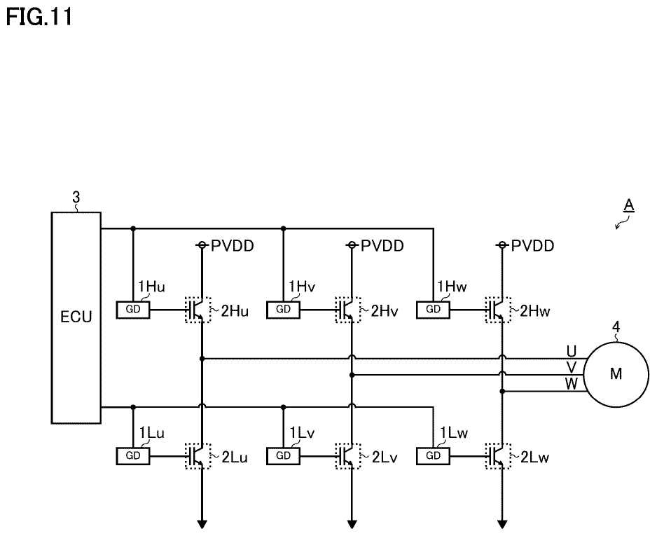

FIG. 11 is a diagram illustrating one configuration example of an electronic device on which the signal transmission device 400 is mounted. The electronic device A of this configuration example includes upper gate driver ICs 1H(u/v/w), lower gate driver ICs 1L(u/v/w), upper power transistors 2H(u/v/w), lower power transistors 2L(u/v/w), an ECU [electronic control unit] 3, and a motor 4.

The upper gate driver ICs 1H(u/v/w), while keeping isolation between the ECU 3 and the upper power transistors 2H(u/v/w), generate upper gate drive signals in response to upper gate control signals inputted from the ECU 3 to drive the upper power transistors 2H(u/v/w), respectively.

The lower gate driver ICs 1L(u/v/w), while keeping isolation between the ECU 3 and the lower power transistors 2L(u/v/w), generate lower gate drive signals in response to lower gate control signals inputted from the ECU 3 to drive the lower power transistors 2L(u/v/w), respectively.

In addition, the upper gate driver ICs 1H(u/v/w) and the lower gate driver ICs 1L(u/v/w) may preferably be implemented by the foregoing signal transmission device 400.

The upper power transistors 2H(u/v/w) are connected, as upper switches forming half-bridge output stages of three phases (u-phase/v-phase/w-phase), between power-system power supply ends (=application ends of load supply voltages PVDD) and individual-phase input ends of the motor 4, respectively.

The lower power transistors 2L(u/v/w) are connected, as lower switches forming half-bridge output stages of three phases (u-phase/v-phase/w-phase), between power-system grounding ends and individual-phase input ends of the motor 4, respectively.

Although the upper power transistors 2H(u/v/w) and the lower power transistors 2L(u/v/w) are implemented by using IGBTs [insulated gate bipolar transistors] respectively in the figure, yet MOSFETs may also be used instead of IGBTs.

The ECU 3 drives the upper power transistors 2H(u/v/w) and the lower power transistors 2L(u/v/w), via the upper gate driver ICs 1H(u/v/w) and the lower gate driver ICs 1L(u/v/w), respectively, to control rotational drive of the motor 4. The ECU 3 further has a function of monitoring fault detection states and self-diagnosis results of the upper gate driver ICs 1H(u/v/w) and the lower gate driver ICs 1L(u/v/w), respectively.

The motor 4 is a three-phase motor which is rotationally driven in response to three phase drive voltages U/V/W inputted from the half-bridge output stages of the three phases (U/V/W), respectively.

### PWM Mode and SPI Communication Mode

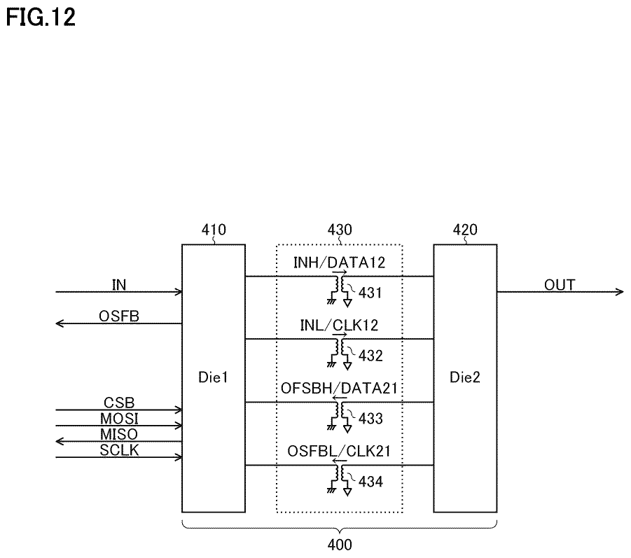

FIG. 12 is a diagram illustrating switching control of operation mode. In more detail, in this figure, insulation elements 431 to 434 integrated together in the third die 430 are used in common to both PWM [pulse width modulation] mode and SPI [serial peripheral interface] communication mode in the signal transmission device 400. The insulation elements 431 to 434 may be transformers.

In the PWM mode, the first die 410 generates a first rise signal INH and a first fall signal INL from an input pulse signal IN which is externally inputted. For example, the first rise signal INH is pulse-driven in response to rising edges of the input pulse signal IN. Meanwhile, the first fall signal INL is pulse-driven in response to falling edges of the input pulse signal IN. The first rise signal INH and the first fall signal INL are transmitted from the first die 410 via the insulation elements 431 and 432, respectively, to the second die 420.

The second die 420 generates an output pulse signal OUT from the first rise signal INH and the first fall signal INL to drive a switching device TR1 (not shown). Also, the second die 420 generates a second rise signal OSFBH and a second fall signal OSFBL in response to on/off states of the switching device TR1. For example, the second rise signal OSFBH is pulse-driven in response to on-transition of the switching device TR1. Meanwhile, the second fall signal OSFBL is pulse-driven in response to off-transition of the switching device TR1. The second rise signal OSFBH and the second fall signal OSFBL are transmitted from the second die 420 via the insulation elements 433 and 434, respectively, to the first die 410.

The first die 410 generates a switch state signal OSFB from the second rise signal OSFBH and the second fall signal OSFBL, and outputs the generated signal to outside. That is, the switch state signal OSFB acts as a pulse signal responsive to the on/off state of the switching device TR1 that is driven by the output pulse signal OUT.

In addition, given that a microcomputer (e.g., ECU) provided outside the signal transmission device 400 monitors the switch state signal OSFB, it becomes possible to confirm whether or not the switching device TR1 is turned on/off, as intended, in response to the input pulse signal IN.

As described above, in the PWM mode, the input pulse signal IN is externally inputted, and the output pulse signal OUT is externally outputted. Also in the PWM mode, the switch state signal OSFB responsive to the on/off state of the switching device TR1 driven by the output pulse signal OUT is externally outputted. Further, in th PWM mode, the first rise signal INH, the first fall signal INL, the second rise signal OSFBH and the second fall signal OSFBL are transmitted bidirectionally between the first die 410 and the second die 420 via the third die 430. The PWM mode can be understood, for example, as a first operation mode for use under a normal drive condition of the switching device TR1.

The first die 410 is also provided with the above-described serial communication function with the microcomputer. For example, the first die 410 transmits and receives, in compliance with the SPI protocol, a chip select signal CSB, an input data signal MOSI, an output data signal MISO, and a clock signal SCLK.

Accordingly, in the SPI communication mode, a first data signal DATA12, a first clock signal CLK12, a second data signal DATA21, and a second clock signal CLK21 are transmitted bidirectionally between the first die 410 and the second die 420 via the third die 430. The SPI communication mode can be understood, for example, as a second operation mode for use in drive-parameter setting of the switching device TR1.

In this connection, the PWM mode and the SPI communication mode are exclusively switchable. That is, the PWM mode and the SPI communication mode are never used concurrently. Therefore, in the signal transmission device 400, the insulation elements 431 to 434 integrated in the third die 430 are shared by both the PWM mode and the SPI communication mode.

According to the figure, the insulation element 431 is shared as a transmission means for both the first rise signal INH and the first data signal DATA12. The insulation element 432 is shared as a transmission means for both the first fall signal INL and the first clock signal CLK12. The insulation element 433 is shared as a transmission means for both the second rise signal OSFBH and the second data signal DATA21. The insulation element 434 is shared as a transmission means for both the second fall signal OSFBL and the second clock signal CLK21.

Thus, given a configuration in which the insulation elements 431 to 434 are shared by both the PWM mode and the SPI communication mode, the insulation elements to be integrated on the third die 430 can be reduced in quantity. For example, when the insulation elements are provided as transmission means for the above-described eight signals (INH, INL, OSFBH, OSFBL, DATA12, CLK12, DATA21, and CLK21) in one-to-one correspondence, there arises a need for eight insulation elements. In contrast to this, according to the configuration of the figure, four insulation elements 431 to 434 suffice.

In addition, the signal transmission device 400 may also be configured so as to go into the PWM mode when a chip select signal CSB externally inputted for selection of a microcomputer's communication target is at high level (=chip-nonselect logic level).

### Signal Transmission Device (First Embodiment)

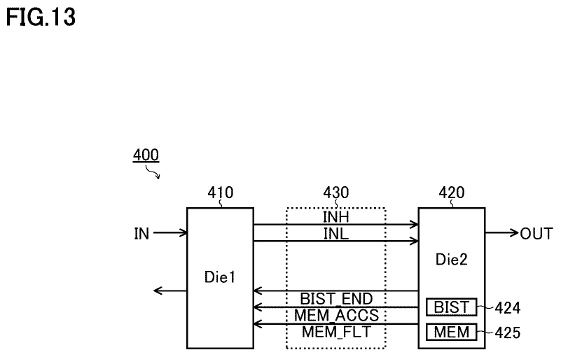

FIG. 13 is a diagram illustrating a first embodiment (=corresponding to a comparative example for contrast with a later-described second embodiment) of the signal transmission device 400. The signal transmission device 400 of this embodiment, as in above-described FIG. 10, includes a first die 410, a second die 420, and a third die 430. The second die 420 includes a self-diagnosis circuit 424 and a storage circuit 425.

The second die 420 generates a self-diagnosis end signal BIST_END, a memory access signal MEM_ACCS, and a memory fault signal MEM_FLT.

The self-diagnosis end signal BIST_END is a signal indicating whether or not a se diagnosis by the self-diagnosis circuit 424 has been ended. This self-diagnosis is executed only once at start-up of the signal transmission device 400.

The memory access signal MEM_ACCS is a signal indicating whether or not memory access to the storage circuit 425 is under execution. The memory access may b e executed any times at timings desired by a user.

The memory fault signal MEM_FLT is a signal indicating whether or not memory access to the storage circuit 425 is faulty. Whether or not memory access is faulty may be decided each time memory access is executed.

The self-diagnosis end signal BIST_END, the memory access signal MEM_ACCS, and the memory fault signal MEM_FLT are transmitted from the second die 420 via the third die 430 to the first die 410. Also, the self-diagnosis end signal BIST_END, the memory access signal MEM_ACCS, and the memory fault signal MEM_FLT may also be externally outputted from the first die 410 to an unshown microcomputer or the like.

In this connection, given that the insulation elements are provided as transmission means for the three signals (BIST_END, MEM_ACCS, and MEM_FLT) in one-to-one correspondence, there arises a need for three insulation elements. Therefore, upsizing of the third die 430 as well as cost increases of the signal transmission device 400 could be involved.

Hereinbelow, in view of the above discussions, there is proposed a second embodiment capable of reducing the insulation elements integrated together on the third die 430.

### Signal Transmission Device (Second Embodiment)

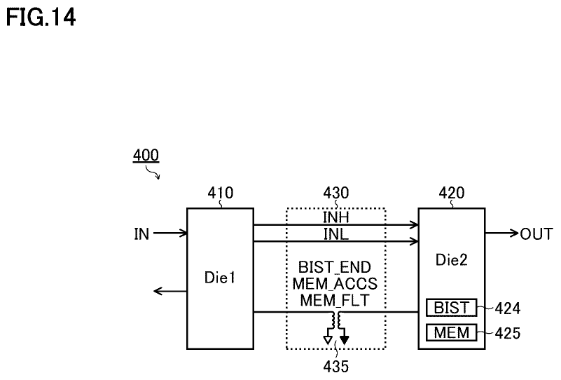

FIG. 14 is a diagram illustrating a second embodiment (outline) of the signal transmission device 400. In the signal transmission device 400 of this embodiment, a single insulation element 435 is shared as a means for transmission of the foregoing self-diagnosis end signal BIST_END, memory access signal MEM_ACCS, and memory fault signal MEM_FLT. With such a configuration, downsizing of the third die 430 and, therefore, cost reduction of the signal transmission device 400 as well, become implementable.

However, given that the single insulation element 435 is shared as a transmission means for the three signals (BIST_END, MEM_ACCS, and MEM_FLT), the first die 410 is required to be able to distinguish which signal is transmitted via the single insulation element 435. A signal discrimination method in the first die 410 will be detailed below.

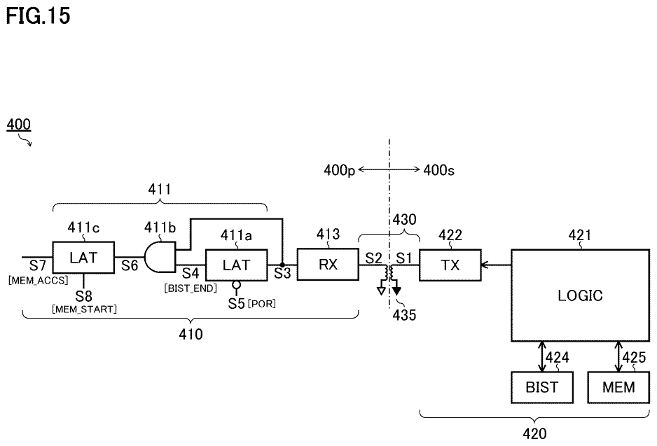

FIG. 15 is a diagram illustrating a second embodiment (particularly, first essential) the signal transmission device 400. In this figure, depicted as the first essential of the signal transmission device 400 is a transmission means for the self-diagnosis end signal BIST_END and the memory access signal MEM_ACCS. It is noted that constituent elements already mentioned hereinabove are denoted by the same reference signs as in FIG. 10.

The transmission circuit 422 generates a single pulse or a plurality of pulses in a transmission pulse signal S1 at each end timing of self-diagnosis by the self-diagnosis circuit 424 and memory access to the storage circuit 425.

The insulation element 435 transmits a transmission pulse signal S1, which is outputted from the transmission circuit 422 of the second die 420, to the reception circuit 413 of the first die 410 as a reception pulse signal S2.

The reception circuit 413 subjects the reception pulse signal S2, which has been inputted via the insulation element 435, to waveform shaping and noise elimination or other process before outputting the processed signal to the logic 411 as a reception pulse signal S3.

The logic 411 (=corresponding to signal processing circuit) distinguishes each end timing of self-diagnosis by the self-diagnosis circuit 424 and memory access to the storage circuit 425 on a basis of the reception pulse signal S3. According to the figure, the logic 411 includes a latch 411a, an AND gate 411b, and a latch 411c.

The latch 411a (=corresponding to first latch) goes to a reset state when a power-on reset signal S5 is at low level. The latch 411a of the reset state holds a self-diagnosis end signal S4 without depending on the reception pulse signal S3. The self-diagnosis end signal S4 corresponds to the foregoing self-diagnosis end signal BIST_END.

The latch 411a goes to a reset-canceled state when the power-on reset signal S5 i high level. The latch 411a of the reset-canceled state, while holding the reception pulse signal S3, generates the self-diagnosis end signal S4. For example, the latch 411a of the reset-canceled state raises the self-diagnosis end signal S4 to high level when a single pulse or a plurality of pulses are generated in the reception pulse signal S3.

In addition, the power-on reset signal S5 keeps at low level (=a logic level for reset state) until the signal transmission device 400 is started up. Also, the power-on reset signal S5 goes to high level (=a logic level for reset-canceled state) when the signal transmission device 400 is started up.

Thus, the latch 411a holds the self-diagnosis end signal S4 at low level until the signal transmission device 400 is started up. The latch 411a also sets the self-diagnosis end signal S4 to high level when a single pulse or a plurality of pulses are generated in the reception pulse signal S3 for the first time since start-up of the signal transmission device 400. Therefore, an end timing of self-diagnosis by the self-diagnosis circuit 424 can be distinguished on a basis of a rise timing of the self-diagnosis end signal S4.

The AND gate 411b generates an AND signal S6 of the reception pulse signal S3 and the self-diagnosis end signal S4. The AND signal S6 goes to low level when at least one of the reception pulse signal S3 and the self-diagnosis end signal S4 is at low level. The AND signal S6 goes to high level when both the reception pulse signal S3 and the self-diagnosis end signal S4 are at high level. That is, when the self-diagnosis end signal S4 is at low level, the AND gate 411b sets the AND signal S6 to low level without depending on the reception pulse signal S3. Meanwhile, when the self-diagnosis end signal S4 is at high level, the AND gate 411b lets the reception pulse signal S3 to be through-outputted as the AND signal S6.

The latch 411c (=corresponding to second latch) goes to a reset state when a memory access start signal S8 is at high level. The latch 411c of the reset state holds a memory access signal S7 at low level without depending on the AND signal S6. The memory access signal S7 corresponds to the foregoing memory access signal MEM_ACCS.

The latch 411c goes to a reset-canceled state when the memory access start signal S8 at low level. The latch 411c of the reset-canceled state, while holding the AND signal S6, generates a memory access signal S7. For example, the latch 411c of the reset-canceled state raises the memory access signal S7 to high level when a single pulse or a plurality of pulses are generated in the AND signal S6.

In addition, a high-level one-shot pulse is generated in the memory access start signal S8 at a start timing of memory access to the storage circuit 425. The start timing of memory access may be, for example, a timing at which a read command or a write command for memory access to the storage circuit 425 is written into the storage circuit 415 (register or the like) of the first die 410.

Thus, the latch 411c sets the memory access signal S7 to low level when memory access to the storage circuit 425 is started. Also, the latch 411c sets the memory access signal S7 to high level when a single pulse or a plurality of pulses are generated in the reception pulse signal S3 under a condition that the self-diagnosis end signal S4 is held at high level. Accordingly, an end timing of memory access to the storage circuit 425 can be distinguished on a basis of a rise timing of the memory access signal S7.

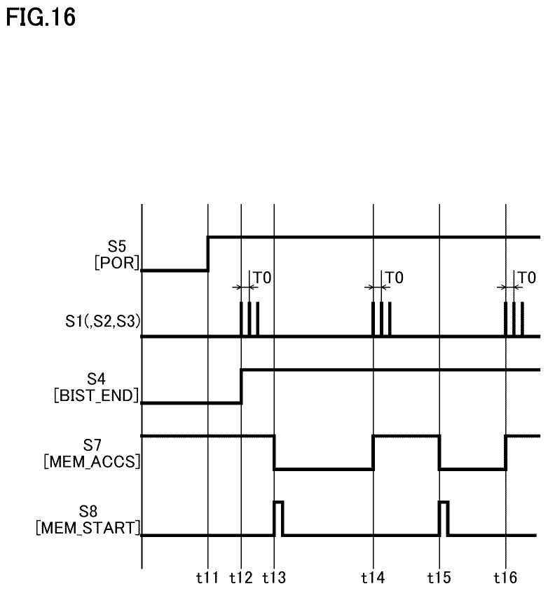

FIG. 16 is a diagram illustrating a first sharing example of the insulation element 435 which is implemented by the foregoing first essential (FIG. 15). In FIG. 16, depicted in descending order from above are a power-on reset signal S5, a transmission pulse signal S1, a self-diagnosis end signal S4, a memory access signal S7, and a memory access start signal S8. It is noted that the transmission pulse signal S1 may be understood as a reception pulse signal S2 or S3.

When the signal transmission device 400 is started up at time t11, the power-on reset signal S5 is raised from low level to high level.

When self-diagnosis by the self-diagnosis circuit 424 is ended at time t12, a single pulse or a plurality of pulses are generated in the transmission pulse signal S1. As the plurality of pulses, for example, three pulses may be intensively generated at 10 MHz (pulse period T0=0.1 μs).

Thus, when a single pulse or a plurality of pulses are generated in the transmission pulse signal S1 (and therefore, reception pulse signal S3), the self-diagnosis end signal S4 rises to high level. Accordingly, an end timing of self-diagnosis by the self-diagnosis circuit 424 can be distinguished on a basis of a rise timing of the self-diagnosis end signal S4. In addition, when the self-diagnosis end signal S4 rises to high level, memory access to the storage circuit 425 is enabled.

When memory access to the storage circuit 425 is started at time t13, a one-shot pulse of high level is generated in the memory access start signal S8. As a result, the memory access signal S7 is reset to low level.

When the memory access to the storage circuit 425 is ended at time t14, a single pulse or a plurality of pulses are generated in the transmission pulse signal S1. As the plurality of pulses, as described above, three pulses may be intensively generated at 10 MHz (pulse period T0=0.1 μs).

In addition, at time t14, the self-diagnosis end signal S4 has been set to high level. Accordingly, the reception pulse signal S3 is through-outputted, as it is, as the AND signal S6. As a result, when a single pulse or a plurality of pulses are generated in the transmission pulse signal S1 (and therefore, reception pulse signal S3), the memory access signal S7 rises to high level. Accordingly, an end timing of the memory access to the storage circuit 425 can be distinguished on a basis of a rise timing of the memory access signal S7. In addition, a low-level duration (from time t13 to time t14) of the memory access signal S7 indicates that memory access to the storage circuit 425 is under execution.

After this and onward, each time memory access to the storage circuit 425 is executed, signal transmission process similar to the above-described one is repeated (see times t15 and t16).

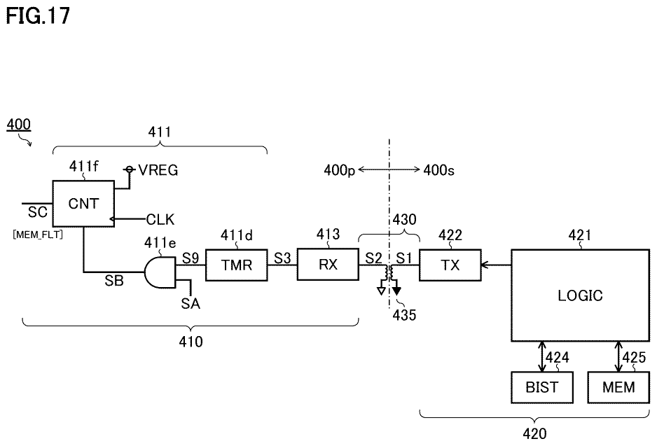

FIG. 17 is a diagram illustrating the second embodiment (particularly, second essential) of the signal transmission device 400. In this figure, a transmission means for the memory fault signal MEM_FLT is depicted as the second essential of the signal transmission device 400. It is noted that constituent elements already mentioned hereinabove are denoted by the same reference signs as in FIG. 10.

While any fault of memory access to the storage circuit 425 is being detected, the transmission circuit 422 continues to generate pulses in the transmission pulse signal S1 at a period of a first time T1. However, pulse generating operation involved in fault detection of the memory access is invalidated until self-diagnoses of the self-diagnosis circuits 414 and 424 are ended. Also in the SPI communication mode, the pulse generating operation is invalidated. It is noted that the first time T1 may appropriately be set to a value enough longer (e.g., T1=5 μs) than the foregoing pulse period T0.

The insulation element 435 transmits a transmission pulse signal S1, which is outputted from the transmission circuit 422 of the second die 420, to the reception circuit 413 of the first die 410 as a reception pulse signal S2.

The reception circuit 413 subjects the reception pulse signal S2, which has been inputted via the insulation element 435, to waveform shaping and noise elimination or other process before outputting the processed signal to the logic 411 as a reception pulse signal S3.

The logic 411 (=corresponding to signal processing circuit) decides, on a basis of reception pulse signal S3, presence or absence of any fault as to memory access to the storage circuit 425. According to the figure, the logic 411 includes a timer 411d, an AND gate 411e, and a counter 411f.

When a pulse is generated in the reception pulse signal S3, the timer 411d sets a timer signal S9 to high level. Also, when no pulse is generated in the reception pulse signal S3 over a duration of a second time T2 (e.g., T2=8 μs) longer than the foregoing first time T1, the timer 411d sets the timer signal S9 to low level.

The AND gate 411e generates an AND signal SB of the timer signal S9 and a UVLO [under voltage locked out] signal SA. The AND signal SB goes to low level when at least one of the timer signal S9 and the UVLO signal SA is at low level. Also, when both the timer signal S9 and the UVLO signal SA are at high level, the AND signal SB goes to high level. That is, when the UVLO signal SA is at low level (=a logic level for UVLO detection), the AND gate 411e sets the AND signal SB to low level without depending on the timer signal S9. Meanwhile, when the UVLO signal SA is at high level (=a logic level for UVLO cancellation), the AND gate 411e through-outputs the timer signal S9, as it is, as the AND signal SB.

When the AND signal SB (corresponding to the timer signal S9 under the UVLO-canceled state; applicable also hereinafter) is at high level, the counter 411f goes to a reset-canceled state. The counter 411f of the reset-canceled state counts number of pulses in an internal clock signal CLK. The internal clock signal CLK may be, for example, a pulse signal of 10 MHz (pulse period of 1 μs).

When the pulse count value has not reached a specified value (e.g., ten pulses), the counter 411f sets a memory fault signal SC to low level. Meanwhile, when the pulse count value has reached a specified value (e.g., ten pulses), the counter 411f sets the memory fault signal SC to high level (in the figure, reference voltage VREF). The memory fault signal SC corresponds to the foregoing memory fault signal MEM_FLT.

Further, when the AND signal SB is at low level, the counter 411f goes to a reset state. The counter 411f of the reset state resets the memory fault signal SC to low level. Also, the counter 411f of the reset state resets the pulse count value of the internal clock signal CLK to an initial value (a value of zero).

Thus, when the timer signal S9 is held at high level over a duration of a third ti T3 (e.g., T3=10 μs) longer the foregoing second time T2, the counter 411f sets the memory fault signal SC to high level. Also, when the AND signal SB is set to low level, the counter 411f sets the memory fault signal SC to low level. Accordingly, presence or absence of any fault of memory access to the storage circuit 425 can be distinguished on a basis of a logic level of the memory fault signal SC.

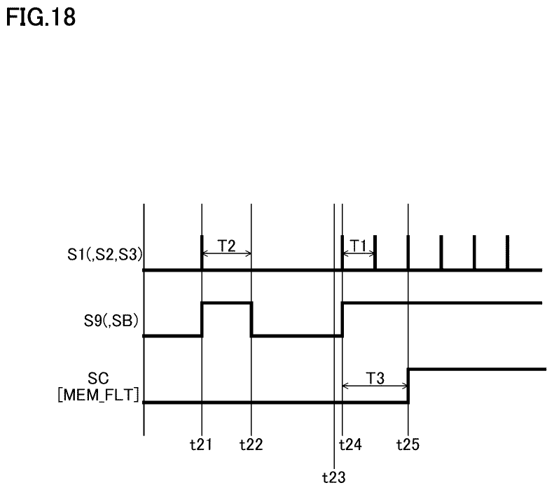

FIG. 18 is a diagram illustrating a second sharing example of the insulation element 435 implemented by the foregoing second essential (FIG. 17). In this figure, depicted are, in descending order from above, a transmission pulse signal S1, a timer signal S9, and a memory fault signal SC. In addition, the transmission pulse signal S1 may also be understood as the reception pulse signal S2 or S3. Furthermore, the timer signal S9 may also be understood as the AND signal SB under the UVLO-canceled state (SA=H).

At time t21, a single pulse or a plurality of pulses are generated in the transmission pulse signal S1. The pulse or pulses, as described above, can be generated at each end timing of self-diagnosis by the self-diagnosis circuit 424 and memory access to the storage circuit 425 (see FIG. 16 described above). It can also be assumed that due to noise superimposition, a single pulse or a plurality of pulses are generated in the transmission pulse signal S1. In such a case, when the pulse or pulses are generated in the transmission pulse signal S1, the timer signal S9 rises to high level.

However, at each end timing of self-diagnosis by the self-diagnosis circuit 424 and memory access to the storage circuit 425, only three pulses are generated intensively at 10 MHz (pulse period of T0=0.1 μs). That is, after time t21 onward, no following pulses are generated.

Accordingly, after a pulse or pulses are generated in the transmission pulse signal S1 at time t21, and when the second time T2 (e.g., T2=8 μs) has elapsed with no succeeding pulses having been generated, the timer signal S9 falls to low level at time t22. Hence, the memory fault signal SC is held at low level.

Thereafter, assume that a fault has occurred to the memory access to the storage circuit 425 at time t23. In this case, after time t24 onward, pulses are continually generated in the transmission pulse signal S1 at a period of the first time T1 (e.g., T1=5 μs). Like this, as a pulse is generated in the transmission pulse signal S1, the timer signal S9 rises to high level.

Then, when the timer signal S9 is held at high level over a duration of the third time T3 (e.g., T3=10 μs) as counted from time t24, the memory fault signal SC rises to high level at time t25. Accordingly, presence or absence of any fault as to memory access to the storage circuit 425 can be distinguished on a basis of the logic level of the memory fault signal SC.

As described above, according to the signal transmission device 400 of this embodiment, the single insulation element 435 is shared as a means for transmission of the above-described self-diagnosis end signal BIST_END, memory access signal MEM_ACCS, and memory fault signal MEM_FLT. Accordingly, downsizing of the third die 430 and, therefore, cost reduction of the signal transmission device 400 become implementable.

In addition, in this disclosure, the first essential (FIG. 15) and the second essential (FIG. 17) of the signal transmission device 400 have been described separately from each other for explanation's sake. However, the first essential (FIG. 15) and the second essential (FIG. 17) are actually implementable, in combination with each other, in the signal transmission device 400 (particularly, logic 411).

### Applications to Vehicle

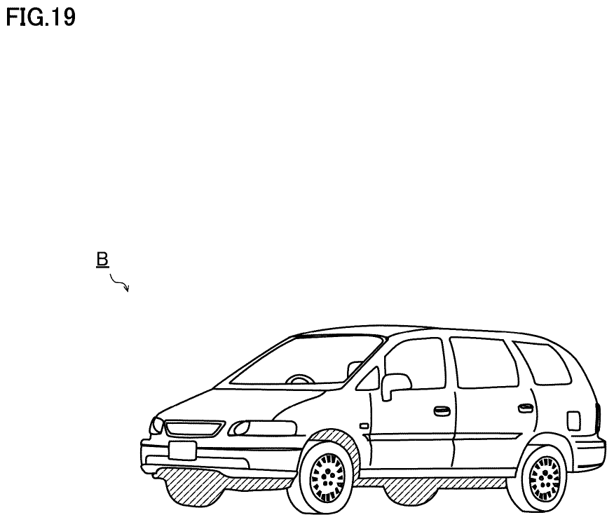

FIG. 19 is a view showing an appearance of a vehicle. The vehicle B of this configuration example is equipped with various electronic devices that operate on power supply from a battery.

The vehicle B may be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

In addition, the signal transmission device 200 or 400 described above may be incorporated into any one of electronic devices that are mountable on the vehicle B.

### Appendices

Appendices relevant to the present disclosure are given below. According to the disclosure, the insulation elements can be reduced.

### Appendix 1

A signal transmission device (400) comprising:
an insulation element (435) configured to perform signal transmission between a primary circuit system (400p) and a secondary circuit system (400s) while keeping isolation therebetween;
a self-diagnosis circuit (424) provided in the secondary circuit system (400s) and configured to perform self-diagnosis of the secondary circuit system (400s);
a storage circuit (425) provided in the secondary circuit system (400s) and configured so as to be permitted to make memory access after an end of the self-diagnosis; and
a transmission circuit (422) provided in the secondary circuit system (400s) and configured to output a transmission pulse signal (S1) to the insulation element (435), wherein
the transmission circuit (422)
generates a single pulse or a plurality of pulses in the transmission pulse signal (S1) at each end timing of the self-diagnosis and the memory access, and
continues to generate pulses at a period of a first time (T1) in the transmission pulse signal (S1) while any fault of the memory access is being detected.

### Appendix 2

The signal transmission device (400) as described in Appendix 1, further comprising a signal processing circuit (411) provided in the primary circuit system (400p) and configured to distinguish each end timing of the self-diagnosis and the memory access, as well as presence or absence of any fault of the memory access, on a basis of a reception pulse signal (S3) inputted via the insulation element (435).

### Appendix 3

The signal transmission device (400) as described in Appendix 2, wherein
the signal processing circuit (411) includes:
a first latch (411a) configured to hold a self-diagnosis end signal (S4) at a first logic level until the signal transmission device (400) is started up, and to set the self-diagnosis end signal (S4) to a second logic level when a single pulse or a plurality of pulses are generated in the reception pulse signal (S3) for a first occurrence time since start-up of the signal transmission device (400); and
a second latch (411c) configured to set a memory access signal (S7) to a third logic level when the memory access has been started, and to set the memory access signal to a fourth logic level when a single pulse or a plurality of pulses are generated in the reception pulse signal (S3) under a state in which the self-diagnosis end signal (S4) is held at the second logic level.

### Appendix 4

The signal transmission device (400) as described in Appendix 2 or 3, wherein
the signal processing circuit (411) includes:
a timer (411d) configured to set a timer signal (S9) to a fifth logic level when pulse is generated in the reception pulse signal (S3), and to set the timer signal (S9) to a sixth logic level when no pulse has been generated in the reception pulse signal (S3) over a duration of a second time (T2) longer than the first time (T1); and
a counter (411f) configured to set a memory fault signal (SC) to a seventh logic level when the timer signal (S9) is held at the fifth logic level over a duration of a third time (T3) longer than the second time (T2), and to set the memory fault signal (SC) to an eighth logic level when the timer signal (S9) is set to the sixth logic level.

### Appendix 5

The signal transmission device (400) as described in any one of Appendices 1 to 4, wherein the insulation element (435) is a transformer.

### Appendix 6

The signal transmission device (400) as described in any one of Appendices 1 to 5, further comprising
a first insulation element (431) and a second insulation element (432) each configured to perform signal transmission between the primary circuit system (400p) and the secondary circuit system (400s) while keeping isolation therebetween, wherein
in a first operation mode, a rising edge and a falling edge of an input pulse signal (IN) are transmitted from the primary circuit system (400p) via the first insulation element (431) and the second insulation element (432) to the secondary circuit system (400s), and
in a second operation mode, a data signal (DATA12) and a clock signal (CLK12) are transmitted from the primary circuit system (400p) via the first insulation element (431) and the second insulation element (432) to the secondary circuit system (400s).

### Appendix 7

The signal transmission device (400) as described in any one of Appendices 1 to 6, further comprising:
a first die (410) on which circuit elements of the primary circuit system (400 are integrated;
a second die (420) on which circuit elements of the second circuit system (400s are integrated; and
a third die (430) on which the insulation element (435) is integrated.

### Appendix 8

The signal transmission device (400) as described in Appendix 7, wherein the f die (410), the second die (420), and the third die (430) are sealed in a single package.

### Appendix 9

An electronic device (A) comprising a power transistor (2), and an insulated ga driver IC (1) configured to drive a gate of the power transistor (2), wherein the insulated gate driver IC (1) is the signal transmission device (400) as described in any one of Appendices 1 to 8.

### Appendix 10

A vehicle (B) comprising the electronic device (A) as described in Appendix 9.

### Others

In addition, various technical features according to the present disclosure may be carried out not only as in the above-described embodiment but also as changed or modified without departing from the gist of the technical creation of the disclosure. That is, the embodiment should be construed as only exemplary at all points and not as limitative. Also, the technical scope of the disclosure is defined by the appended claims and should be understood as including all changes and modifications equivalent in sense and range to the claims.

1. A signal transmission device comprising:
an insulation element configured to perform signal transmission between a primary circuit system and a secondary circuit system while keeping isolation therebetween;
a self-diagnosis circuit provided in the secondary circuit system and configured to perform self-diagnosis of the secondary circuit system;
a storage circuit provided in the secondary circuit system and configured so as to be permitted to make memory access after an end of the self-diagnosis; and
a transmission circuit provided in the secondary circuit system and configured output a transmission pulse signal to the insulation element, wherein
the transmission circuit
generates a single pulse or a plurality of pulses in the transmission pulse signal at each end timing of the self-diagnosis and the memory access, and
continues to generate pulses at a period of a first time in the transmission pulse signal while any fault of the memory access is being detected.

2. The signal transmission device as claimed in claim 1, further comprising a signal processing circuit provided in the primary circuit system and configured to distinguish each end timing of the self-diagnosis and the memory access, as well as presence or absence of any fault of the memory access, on a basis of a reception pulse signal inputted via the insulation element.

3. The signal transmission device as claimed in claim 2, wherein
the signal processing circuit includes:
a first latch configured to hold a self-diagnosis end signal at a first logic level until the signal transmission device is started up, and to set the self-diagnosis end signal to a second logic level when a single pulse or a plurality of pulses are generated in the reception pulse signal for a first occurrence time since start-up of the signal transmission device; and
a second latch configured to set a memory access signal to a third logic level when the memory access has been started, and to set the memory access signal to a fourth logic level when a single pulse or a plurality of pulses are generated in the reception pulse signal under a state in which the self-diagnosis end signal is held at the second logic level.

4. The signal transmission device as claimed in claim 2, wherein
the signal processing circuit includes:
a timer configured to set a timer signal to a fifth logic level when a pulse is generated in the reception pulse signal, and to set the timer signal to a sixth logic level when no pulse has been generated in the reception pulse signal over a duration of a second time longer than the first time; and
a counter configured to set a memory fault signal to a seventh logic level when the timer signal is held at the fifth logic level over a duration of a third time longer than the second time, and to set the memory fault signal to an eighth logic level when the timer signal is set to the sixth logic level.

5. The signal transmission device as claimed in claim 1, wherein the insulation element is a transformer.

6. The signal transmission device as claimed in claim 1, further comprising
a first insulation element and a second insulation element each configured to perform signal transmission between the primary circuit system and the secondary circuit system while keeping isolation therebetween, wherein
in a first operation mode, a rising edge and a falling edge of an input pulse signal are transmitted from the primary circuit system via the first insulation element and the second insulation element to the secondary circuit system, and
in a second operation mode, a data signal and a clock signal are transmitted from the primary circuit system via the first insulation element and the second insulation element to the secondary circuit system.

7. The signal transmission device as claimed in claim 1, further comprising:
a first die on which circuit elements of the primary circuit system are integrated;
a second die on which circuit elements of the second circuit system are integrated; and
a third die on which the insulation element is integrated.

8. The signal transmission device as claimed in claim 7, wherein the first die, the second die, and the third die are sealed in a single package.

9. An electronic device comprising a power transistor, and an insulated gate driver IC configured to drive a gate of the power transistor, wherein the insulated gate driver IC is the signal transmission device as claimed in claim 1.

10. A vehicle comprising the electronic device as claimed in claim 9.
